(19) United States
(12) Patent Application Publication
(10) Pub. No.: US 2002/0027398 A1
(43) Pub. Date: Mar. 7, 2002

(54) Method for manufacturing thin plate, piezoelectric plate, and piezoelectric vibrator

(76) Inventors: Noboru Ueda, Kumamoto (JP); Mutsumi Touge, Kumamoto (JP)

Correspondence Address: STAAS & HALSEY LLP, 700 11TH STREET, NW, SUITE 500, WASHINGTON, DC, 20001, US

(21) Appl. No.: 09/798,037

(22) Filed: Mar. 5, 2001

(30) Foreign Application Priority Data
Sep. 5, 2000 (JP) 2000-268170

(51) Int. Cl. H01L 41/04

(52) U.S. Cl. 310/320; 310/312; 310/367; 310/369

(57) ABSTRACT

A method for manufacturing a thin plate includes steps of: securing the thin plate at a mounting platform; forming a metal plating film in contact with an external circumferential surface of the thin plate on a surface of the mounting platform; and grinding the thin plate until the thin plate achieves a specific thickness.

### INCORPORATION BY REFERENCE

The disclosure of the following priority application is herein incorporated by reference: Japanese Patent Application No. 2000-268170 filed Sep. 5, 2000

### BACKGROUND OF THE INVENTION

1. Field of the Invention

The present invention relates to a method for manufacturing a thin plate that makes it possible to grind a thin plate such as a piezoelectric plate, a typical example of which is a quartz oscillator (a crystal unit), down to a thickness of several μm.

2. Description of the Related Art

A quartz oscillator has been used in application as an oscillating element in a mobile telephone and a frequency control element in the prior art. As recent technical requirements call for an increasingly higher clock frequency in an MPU mounted at a personal computer, a PDA or the like and an equally high oscillation frequency in an oscillating element in a mobile telephone, the quartz oscillator utilized as the oscillating element in the mobile telephone or the frequency control element, too, needs to achieve a high frequency.

The resonance frequency f (MHz) of a quartz oscillator adopting a standard thickness-shear vibration mode is in reverse proportion to the plate thickness y0(μm) and may be expressed as f=1670/y0. Thus, the quartz (crystal) plate of the quartz oscillator is ground to achieve the thickness calculated in correspondence to the desired resonance frequency. In recent years, quartz plates having a thickness of 30 μm are mass-produced through the double-sided grinding method described below.

(1) A quartz plate having a thickness of approximately 100 μm is held in a carrier having a thickness of 30 μm.

(2) The two surfaces of the quartz plate is lapped by using a coarse abrasive with a large abrasive grain size.

(3) The two surfaces of the quartz plate are then polished by using a fine abrasive with a small abrasive grain size.

However, since the thickness of the carrier holding the quartz plate cannot be reduced to an excessive degree, the 30 μm thickness is the limit that can be achieved in the mass production technology by adopting the double-sided grinding method in the prior art described above.

### SUMMARY OF THE INVENTION

An object of the present intention is to provide a method for manufacturing a thin plate that makes it possible to grind the thin plate down to a thickness of several μm.

Another object of the present invention is to provide a piezoelectric plate manufactured through the manufacturing method described above and a piezoelectric vibrator (oscillator) that is achieved by using this piezoelectric plate.

In order to attain the above object, a method for manufacturing a thin plate, according to the present invention, comprises steps of: securing the thin plate at a mounting platform; forming a metal plating film in contact with an external circumferential surface of the thin plate on a surface of the mounting platform; and grinding the thin plate until the thin plate achieves a specific thickness.

Another method for manufacturing a thin plate, according to the present invention, comprises steps of: securing the thin plate at a mounting platform with a first surface of the thin plate assigned as a grinding surface; grinding the first surface of the thin plate; disengaging the thin plate with the first surface having been ground from the mounting platform; securing the thin plate at the mounting platform with a second surface opposite from the first surface assigned as a grinding surface; forming a metal plating film in contact with an external circumferential surface of the thin plate on a surface of the mounting platform; and grinding the second surface until the thin plate achieves a specific thickness.

In this method for manufacturing a thin plate, it is preferred that the first surface of the thin plate is ground by covering the external circumferential surface of the thin plate with a protective ring.

In the above methods for manufacturing a thin plate, it is preferred that the specific thickness is smaller than 30 μm and equal to or larger than 2 μm.

Also, it is preferred that a thickness of the metal plating film is larger than the specific thickness.

Also, it is preferred that the metal plating film is formed through electroplating.

A piezoelectric plate according to the present invention comprises a specific thickness, and the specific thickness is achieved by securing a piezoelectric plate having a larger thickness than the specific thickness at a mounting platform, forming a metal plating film in contact with an external circumferential surface of the piezoelectric plate having the larger thickness than the specific thickness on a surface of the mounting platform and then grinding the piezoelectric plate having the larger thickness than the specific thickness down to the specific thickness.

An piezoelectric vibrator according to the present invention, comprises: a piezoelectric plate having a specific thickness; a lead wire connected to an electrode formed at two surfaces of the piezoelectric plate; a base that holds the lead wire; and a case mounted at the base to house the piezoelectric plate. The specific thickness of the piezoelectric plate is achieved by securing a piezoelectric plate having a larger thickness than the specific thickness at a mounting platform, forming a metal plating film in contact with an external circumferential surface of the piezoelectric plate having the larger thickness than the specific thickness on the surface of the mounting platform and then grinding the piezoelectric plate having the larger thickness than the specific thickness down to the specific thickness.

Another piezoelectric plate according to the present invention comprises a specific thickness, and the specific thickness is achieved by: securing a first piezoelectric plate having a thickness larger than the specific thickness at a mounting platform with a first surface of the first piezoelectric plate assigned as a grinding surface; grinding the first surface of the first piezoelectric plate; disengaging the first piezoelectric plate with the first surface having been ground from the mounting platform; securing the first piezoelectric plate with the first surface having been ground at the mounting platform with a second surface opposite from the first surface assigned as a grinding surface; forming a metal plating film in contact with an external circumferential surface of the first piezoelectric plate with the first surface having been ground on a surface of the mounting platform; and grinding the second surface until the first piezoelectric plate with the first surface having been ground achieves the specific thickness.

A piezoelectric vibrator according to the present invention comprises: a piezoelectric plate having a specific thickness; a lead wire connected to an electrode formed at two surfaces of the piezoelectric plate; a base that holds the lead wire; and a case mounted at the base to house the piezoelectric plate. And the specific thickness is achieved by: securing a first piezoelectric plate having a thickness larger than the specific thickness at a mounting platform with a first surface of the first piezoelectric plate assigned as a grinding surface; grinding the first surface of the first piezoelectric plate; disengaging the first piezoelectric plate with the first surface having been ground from the mounting platform; securing the first piezoelectric plate with the first surface having been ground at the mounting platform with a second surface opposite from the first surface assigned as a grinding surface; forming a metal plating film in contact with an external circumferential surface of the first piezoelectric plate with the first surface having been ground on a surface of the mounting platform; and grinding the second surface until the first piezoelectric plate with the first surface having been ground achieves the specific thickness.

In the above piezoelectric vibrators, it is preferred that the specific thickness of the piezoelectric plate is smaller than 30 μm and equal to or larger than 2 μm.

### BRIEF DESCRIPTION OF THE DRAWINGS

FIGS. 1A-1E illustrate a procedure through which a quartz plate is ground in the method for manufacturing a piezoelectric plate according to the present invention;

FIGS. 2A-2E illustrate the procedure through which the quartz plate is ground, presented in continuation from FIG. 1;

FIG. 3 is a plan view of FIG. 2B;

FIG. 4 illustrates in detail a quartz oscillator achieved by packaging quartz plate;

FIGS. 5A and 5B present conceptual diagrams of the lapping/polishing apparatus; and

FIG. 6 is a perspective of a mounting platform having a plurality of quartz plates bonded thereon and a protective plating applied around them.

### DESCRIPTION OF THE PREFERRED EMBODIMENT

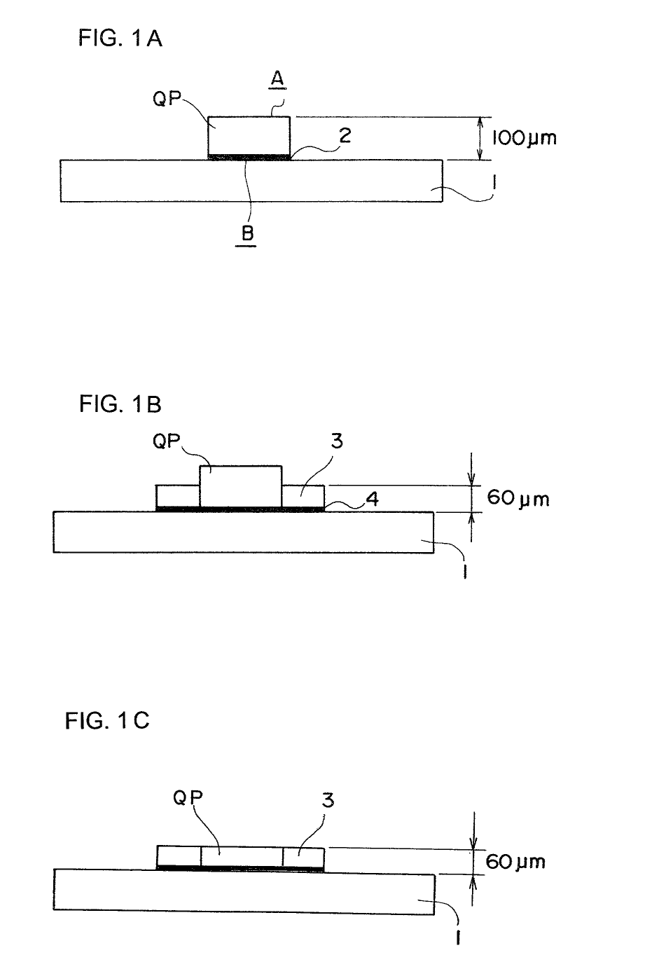

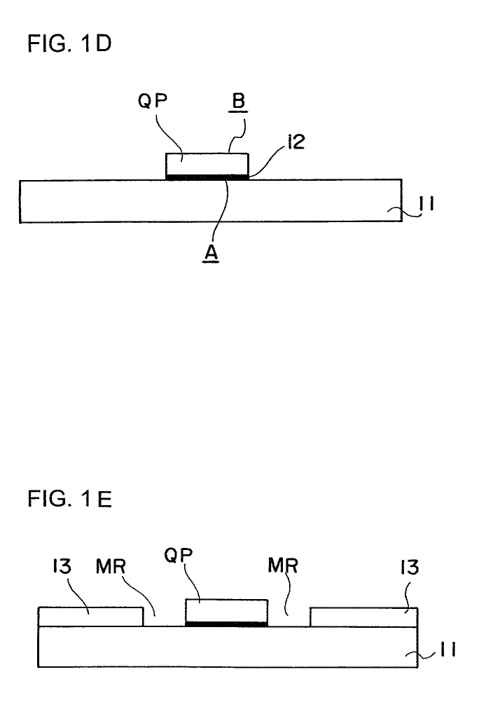

In reference to FIGS. 1-5, a procedure through which a quartz plate is processed to achieve a thickness of 5-6 μm in the thin plate manufacturing method according to the present invention is explained.

(1) A quartz plate QP having a thickness of 100 μm and the diameter of 5 mm prepared in advance is bonded onto a ceramic mounting platform 1 with an adhesive 2 (FIG. 1A). The quartz plate bonding surface of the ceramic mounting platform 1 is mirror finished in advance. In the following explanation, the surface of the quartz plate QP which is to be lapped and the surface of the quartz plate QP which is to be bonded through the process shown in FIG. 1A are respectively referred to as a first surface A and a second surface B.

(2) An iron washer 3 formed in a ring shape having a thickness of 60 μm and an internal diameter of 5 mm is bonded with an adhesive 4 so as to enclose the quartz plate QP (FIG. 1B).

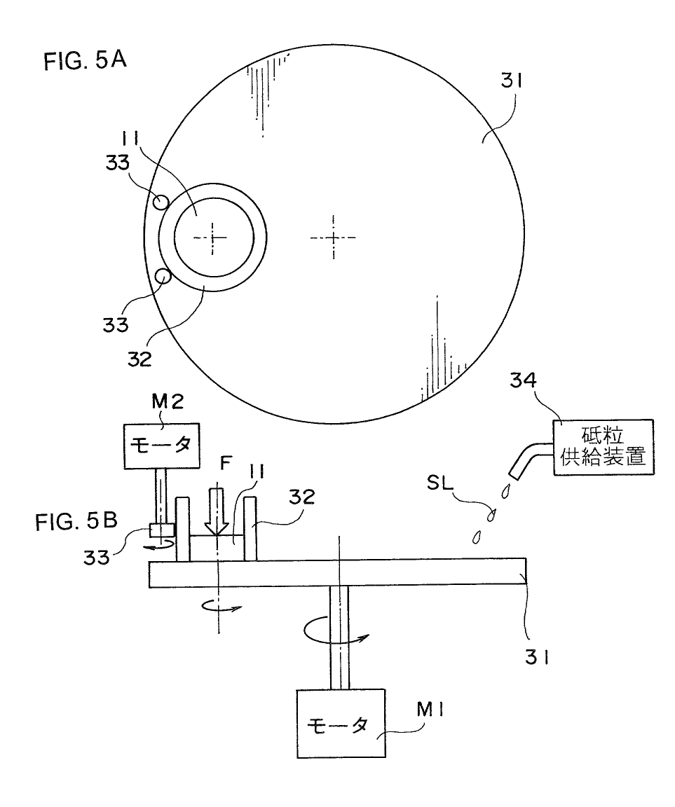

(3) By using a tin surface plate (see FIG. 5), a lapping process is implemented on the quartz plate QP while supplying an abrasive containing GC2000 abrasive grains to achieve a thickness of 60 μm (FIG. 1C).

(4) The entire mounting platform 1 is soaked in an acetone solution and the quartz plate QP is disengaged together with the iron washer 3 from the ceramic mounting platform 1.

(5) The first surface A of the quartz plate QP having the thickness of 60 μm thus disengaged is then bonded onto a brass mounting platform 11 with an adhesive 12 (FIG. 1D). The quartz plate bonding surface of the brass mounting platform 11 is mirror finished in advance.

(6) A plating mask 13 is formed at the mounting platform 11 over a predetermined distance MR from the periphery of the quartz plate QP (FIG. 1E). The plating mask 13 is constituted of an insulating tape. The gap MR constitutes a plating film forming area.

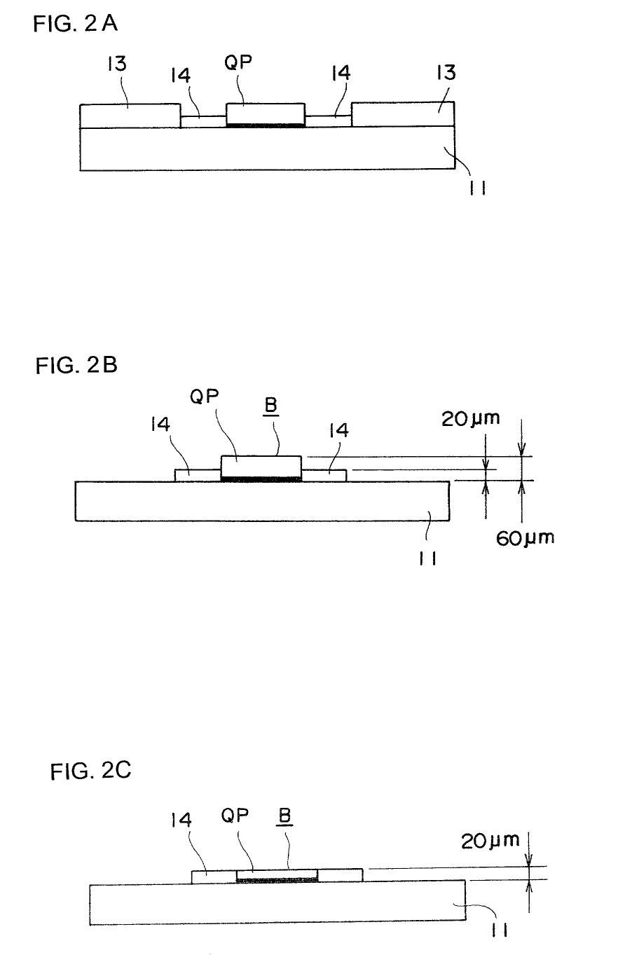

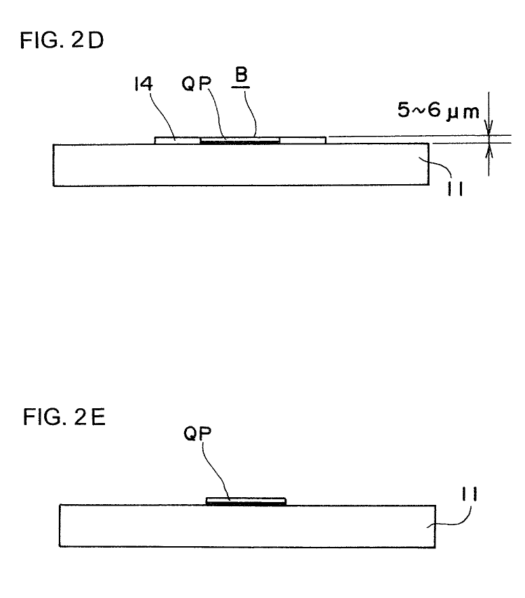

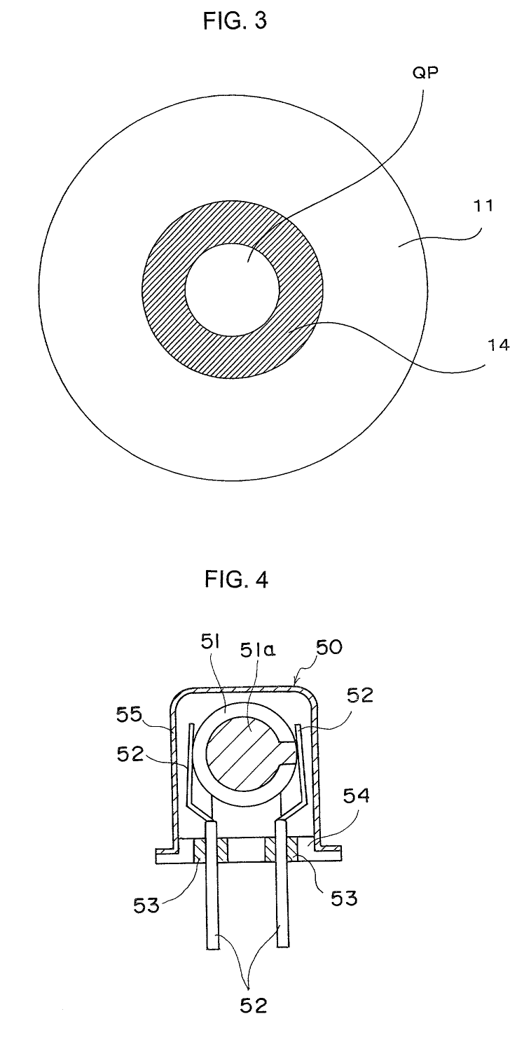

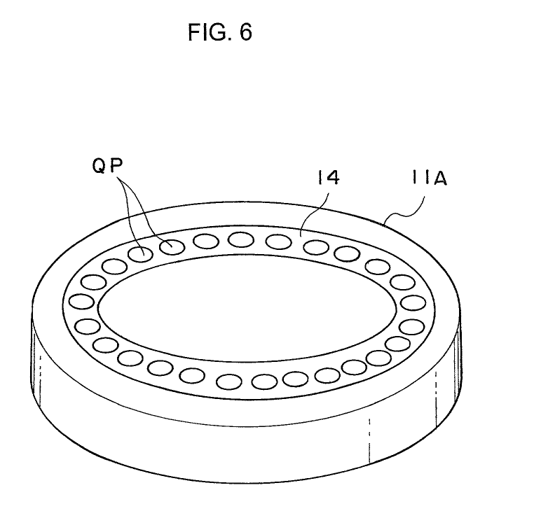

(7) The entire mounting platform 11 is soaked in a nickel sulfate plating solution and a nickel plating film 14 with a thickness of 20 μm is formed through electroplating (FIG. 2A). It is to be noted that FIG. 3 presents a plan view of FIG. 2B. While a single quartz plate QP is mounted at the mounting platforms 1 and 11 and is then ground in the explanation given in reference to FIGS. 1A-3, a plurality of quartz plates QP are mounted at a mounting platform 11A as shown in FIG. 6 during the actual process.

(8) After the mask 13 is removed and the quartz plate QP is washed, the second surface B of the quartz plate QP is lapped by supplying an abrasive containing GC2000 abrasive grains (FIG. 2B).

(9) The lapping process is continuously implemented by switching to an abrasive containing GC4000 abrasive grains to grind the quartz plate QP down to a 20 μm thickness (FIG. 2C).

(10) By using a tin surface plate having an elastic nonwoven cloth placed on its upper surface, a polishing process is implemented while supplying an abrasive containing SiO₂ abrasive grains. This process is continually implemented with the rotation rate of the tin surface plate having the non-woven cloth placed on it and the rotation rate of the brass mounting platform 11 set to 60 rpm and the processing pressure set at 21.8 kPa, until the quartz plate QP achieves a thickness of 5-6 μm (FIG. 2D). It is to be noted that the processing speed for the polishing process should be set sufficiently lower than the processing speed for the lapping process.

(11) Subsequently, the nickel plating film 14 is released from the surface of the mounting platform 11 with a plating release agent (FIG. 2E).

(12) The entire brass mounting platform 11 is soaked in an acetone solution to release the quartz plate QP from the brass mounting platform 11.

(13) The quartz plate QP disengaged from the brass mounting platform 11 is washed, and electrode films are formed at its two surfaces through sputtering or the like. Then, it is packaged as shown in FIG. 4 to obtain a quartz oscillator 50.

By grinding the quartz plate QP through the procedure described above, the metal plating film 14 is formed in contact with the external circumferential surface of the piezoelectric plate QP on the surface of the mounting platform 11 to protect the external circumference of the piezoelectric plate QP. As a result;

1. The abrasive grains that moved in a fluid movement on the surface plate do not directly collide with the side surface of the quartz plate QP.

2. Since there is no gap between the external circumferential surface of the quartz plate QP and the plating film 14, the quartz plate QP is prevented from moving along the horizontal direction during the grinding process.

3. The plating film 14 is bonded onto the mounting platform 11 firmly.

Thus, the surface of the quartz plate QP is prevented from sagging due to the concentrated stress at peripheral area of the quartz plate QP and stable grinding is enabled to achieve a quartz plate QP that has been ground to achieve a uniform thickness of 5-6 μm. Furthermore, by using the plating film 14 as a protective film provided at the external circumferential area of the quartz plate QP, the protective film can be easily formed in contact with the external circumferential surface of a quartz plate QP formed in a shape other than a circular shape (such as a rectangular shape or a tuning fork shape) with a mask formed in the corresponding shape, as well.

It is to be noted that when grinding a single side while protecting the external circumferential edge of a quartz plate with an iron protective ring having a thickness of 30 μm or less, warping occurs at the peripheral area if the grinding rate is set high. This means that the process cannot be implemented at a grinding rate suitable for mass production. However, if a single side grinding process is implemented by protecting the external circumferential edge of the quartz plate with the plating protective film described above, the quartz plate can be processed to achieve a 5-6 μm thickness at a grinding rate suitable for mass production.

FIG. 4 illustrates an example of a quartz oscillator. In FIG. 4, a quartz oscillator 50 comprises a quartz plate 51 having been processed to a 5-6 μm thickness through the procedure described above, lead wires 52 each bonded to an electrode 51a at the quartz plate 51, a base 54 holding the lead wires 52 via glass pellets 53 and a case 55 mounted at the base 54 to house the quartz plate 51 by sealing it in a vacuum. It is to be noted that while it is desirable to achieve the highest possible degree of vacuum within the case 55, it is not always necessary to achieve a perfect vacuum state. Alternatively, instead of achieving a vacuum state, an inert gas or the like may be charged into the space inside the case 55.

FIG. 5 presents conceptual diagrams of the grinding apparatus that is engaged in the lapping process and the polishing process. A tin surface plate 31 is caused to rotate by a motor M1 in the direction indicated by the arrow. Near the upper surface of the surface plate 31, a corrective ring 32 is provided perpendicular to the upper surface. The brass mounting platform 11 is fitted in the corrective ring 32, to constitute an integrated unit. The corrective ring 32 is caused to slide in contact against a pair of drive rollers 33 due to the centrifugal force caused by the rotation of the surface plate 31. Since the pair of drive rollers are rotated by a motor M2 in a direction opposite from the direction of rotation of the surface plate 31, the corrective ring 32 rotates along the same direction as the direction of the rotation of the surface plate 31, at a rotation rate corresponding to the rotation rate of the drive rollers 33. As a result, the mounting platform 11, too, rotates at the same rotation rate along the same direction as the direction of the rotation of the surface plate 31. An abrasive containing an appropriate type of abrasive grains having an appropriate grain size is supplied onto the surface plate 31 from an abrasive supply device 34. The grinding process is implemented by pressing the mounting platforms 1 and 11 at which the quartz plate QP is mounted against the surface plate 31 with a predetermined load F. It is to be noted that the surface plate 31 may be manufactured by using another metal material achieving elasticity such as cast-iron instead of tin.

FIG. 6 presents a specific example of the brass mounting platform 11A used in mass production. At the circumferential edge of the brass mounting platform 11A, quartz plates QP are bonded over specific intervals, with the nickel plating film 14 formed around the quartz plates QP. In mass production, a plurality of brass mounting platforms 11A shown in the FIG. 6 are placed on the surface plate 31 to process a great many quartz plates at once.

In the explanation given above, the quartz plate QP having a thickness of 100 μm is used as the base material, a quartz plate with a thickness of 60 μm is obtained by grinding the first surface A through a lapping process implemented while protecting the periphery with the iron washer 3 (a preliminary process), the quartz plate is ground down to a thickness of approximately 20 μm next through a lapping process implemented on the second surface B of the quartz plates with its external circumferential area protected through nickel plating, and then a polishing process is implemented to reduce the thickness down to 5-6 μm (a post-process). The embodiment is primarily characterized by the polishing process implemented with the periphery of the quartz plate protected with the nickel plating. Thus, the quartz plate processed to achieve the 60 μm thickness through the preliminary process may be used as a base material, to start the main process with the step shown in FIG. 1D. In such a case, the piezoelectric plate should be processed by securing the piezoelectric plate QP at the mounting platform 11, forming a metal plating film 14 in contact with the external circumferential surface of the piezoelectric plate QP on the surface of the mounting platform 11, then lapping the piezoelectric plate QP until it achieves a thickness of approximately 20 μm and finally polishing the piezoelectric plate QP until it achieves a thickness of 5-6 μm. It is to be noted that the polishing process may be implemented after the piezoelectric plate QP has been ground to a thickness of less than 20 μm instead.

The metal material to constitute the plating film is not limited to nickel, and an optimal metal material should be selected in correspondence to the desired grinding rate to form a plating film. For instance, any of corrosion resistant metals such as copper, chromium and tungsten may be used. The thickness of the plating film is not limited to 20 μm, either. The thickness of the plating film should be selected in correspondence to the ultimate thickness that the quartz plate QP is to achieve. In addition, the plating film may be formed through electroless plating or any other plating method, instead of electroplating. In other words, any plating method may be adopted as long as a metal plating film having a specific thickness can be formed.

While an explanation is given above on an example in which a quartz plate to be used in a quartz oscillator is manufactured, the present invention may be adopted to process a piezoelectric plate to be utilized in various applications, including a PZT piezoelectric element and a ceramic piezoelectric element. By further reducing the polishing rate or the like, the quartz plate can be ground (without causing surface sagging) to achieve a uniform thickness as small as 2 μm. A resonance frequency of the resulting quartz plate is 835 MHz. It is to be noted that the present invention may also be adopted to process an ultra thin plate optical element such as a wave plate. In addition, the present invention may be adopted when processing a thin plate constituting a silicon substrate as well. In short, it may be adopted in all types of applications through which thin plates are manufactured.

While an explanation is given above on an example in which a circular quartz plate QP is manufactured, the shape of the thin plate is not limited to this circular shape, and it may be formed in a rectangular shape or any other shape.

As described above, the periphery of a thin plate such as a piezoelectric plate, a typical example of which is a quartz plate, is protected with a plating film while the thin plate is ground, to allow the thin plate to be ground to a thickness of 2 μm. In addition, since the plating protective film is provided at the external circumferential area of the thin plate through plating, a protective film is easily formed simply by forming the mask in the shape corresponding to the external shape of the thin plate. The piezoelectric plate manufactured through this process is capable of oscillating at a high resonance frequency. Thus, an oscillator (vibrator) constituted with this piezoelectric plate is capable of generating a signal with a high oscillation frequency. Moreover, an electronic oscillator device achieving a high frequency can be manufactured by using this oscillator.

What is claimed is;

1. A method for manufacturing a thin plate, comprising steps of:
securing the thin plate at a mounting platform;
forming a metal plating film in contact with an external circumferential surface of the thin plate on a surface of said mounting platform; and
grinding the thin plate until the thin plate achieves a specific thickness.

2. A method for manufacturing a thin plate according to claim 1, wherein:
the specific thickness is smaller than 30 μm and equal to or larger than 2 μm.

3. A method for manufacturing a thin plate according to claim 1, wherein:
a thickness of said metal plating film is larger than the specific thickness.

4. A method for manufacturing a thin plate according to claim 1, wherein:
said metal plating film is formed through electroplating.

5. A piezoelectric plate comprising a specific
thickness, wherein
said specific thickness is achieved by securing a piezoelectric plate having a larger thickness than the specific thickness at a mounting platform, forming a metal plating film in contact with an external circumferential surface of said piezoelectric plate having the larger thickness than the specific thickness on a surface of said mounting platform and then grinding said piezoelectric plate having the larger thickness than the specific thickness down to the specific thickness.

6. A piezoelectric plate according to claim 5, wherein:
the specific thickness is smaller than 30 μm and equal to or larger than 2 μm.

7. An piezoelectric vibrator, comprising:
a piezoelectric plate having a specific thickness;
a lead wire connected to an electrode formed at two surfaces of said piezoelectric plate;
a base that holds said lead wire; and
a case mounted at said base to house said piezoelectric plate, wherein:
the specific thickness of said piezoelectric plate is achieved by securing a piezoelectric plate having a larger thickness than the specific thickness at a mounting platform, forming a metal plating film in contact with an external circumferential surface of said piezoelectric plate having the larger thickness than the specific thickness on the surface of said mounting platform and then grinding said piezoelectric plate having the larger thickness than the specific thickness down to the specific thickness.

8. A piezoelectric vibrator according to claim 7, wherein:
the specific thickness of said piezoelectric plate is smaller than 30 μm and equal to or larger than 2 μm.

9. A method for manufacturing a thin plate, comprising steps of:
securing the thin plate at a mounting platform with a first surface of the thin plate assigned as a grinding surface;
grinding said first surface of the thin plate;
disengaging the thin plate with said first surface having been ground from said mounting platform;
securing the thin plate at said mounting platform with a second surface opposite from said first surface assigned as a grinding surface;
forming a metal plating film in contact with an external circumferential surface of the thin plate on a surface of said mounting platform; and
grinding said second surface until the thin plate achieves a specific thickness.

10. A method for manufacturing a thin plate according to claim 9, wherein:
said first surface of the thin plate is ground by covering the external circumferential surface of the thin plate with a protective ring.

11. A method for manufacturing a thin plate according to claim 9, wherein:
the specific thickness is smaller than 30 μm and equal to or larger than 2 μm.

12. A method for manufacturing a thin plate according to claim 9, wherein
a thickness of said metal plating film is larger than the specific thickness.

13. A method for manufacturing a thin plate according to claim 9, wherein:
said metal plating film is formed through electroplating.

14. A piezoelectric plate comprising a specific thickness, wherein said specific thickness is achieved by:
securing a first piezoelectric plate having a thickness larger than the specific thickness at a mounting platform with a first surface of said first piezoelectric plate assigned as a grinding surface;
grinding said first surface of said first piezoelectric plate;
disengaging said first piezoelectric plate with said first surface having been ground from said mounting platform;
securing said first piezoelectric plate with said first surface having been ground at said mounting platform with a second surface opposite from said first surface assigned as a grinding surface;
forming a metal plating film in contact with an external circumferential surface of said first piezoelectric plate with said first surface having been ground on a surface of said mounting platform; and
grinding said second surface until said first piezoelectric plate with said first surface having been ground achieves the specific thickness.

15. A piezoelectric plate according to claim 14, wherein:
the specific thickness is smaller than 30 μm and equal to or larger than 2 μm.

16. A piezoelectric vibrator comprising:
a piezoelectric plate having a specific thickness;
a lead wire connected to an electrode formed at two surfaces of said piezoelectric plate;
a base that holds said lead wire; and
a case mounted at said base to house said piezoelectric plate, wherein the specific thickness is achieved by:
securing a first piezoelectric plate having a thickness larger than the specific thickness at a mounting platform with a first surface of said first piezoelectric plate assigned as a grinding surface;
grinding said first surface of said first piezoelectric plate;
disengaging said first piezoelectric plate with said first surface having been ground from said mounting platform;
securing said first piezoelectric plate with said first surface having been ground at said mounting platform with a second surface opposite from said first surface assigned as a grinding surface;
forming a metal plating film in contact with an external circumferential surface of said first piezoelectric plate with said first surface having been ground on a surface of said mounting platform; and
grinding said second surface until said first piezoelectric plate with said first surface having been ground achieves the specific thickness.

17. A piezoelectric vibrator according to claim 16, wherein:
the specific thickness of said piezoelectric plate is smaller than 30 μm and equal to or larger than 2 μm.
